(19) United States
(12) Patent Application Publication
(10) Pub. No.: US 2009/0146300 A1
(43) Pub. Date: Jun. 11, 2009

(54) Semiconductor packages and electronic products employing the same

(76) Inventors: Se-Young Yang, Seongnam-si (KR); Ho-Jeong Moon, Cheonan-si (KR); Seung-Woo Kim, Asan-si (KR); Hyun Kyung Han, Seoul (KR)

Correspondence Address: HARNESS, DICKEY & PIERCE, P.L.C., P.O. BOX 8910, RESTON, VA, 20195, US

(21) Appl. No.: 12/292,569

(22) Filed: Nov. 21, 2008

(30) Foreign Application Priority Data
Nov. 21, 2007 (KR) 10-2007-0119345

(51) Int. Cl. H01L 23/498

(52) U.S. Cl. 257/738; 257/E23.069

(57) ABSTRACT

Example embodiments of a semiconductor package are provided. In accordance with an example embodiment, a semiconductor package may include an external terminal connected to a concave surface of a bottom pad, wherein the bottom pad is recessed into a substrate. In accordance with another example embodiment, a semiconductor package may include at least one external terminal, a flexible substrate having a first surface with a plurality of convex portions and a second surface opposite the first surface having a plurality of concave portions, wherein the at least one terminal is recessed into the substrate and at least one of the concave portions surrounds a portion of the at least one external terminal.

### PRIORITY STATEMENT

This application claims priority under 35 U.S.C. § 119 to Korean Patent Application No. 10-2007-0119345, filed on Nov. 21, 2007, in the Korean Intellectual Property Office (KIPO), the entire contents of which are incorporated herein by reference.

### BACKGROUND

1. Field

Example embodiments relate to semiconductor packages and electronic products employing the same.

2. Description of the Related Art

The demand for an increase in the memory capacity of electronic products has driven the industry to produce relatively large and highly integrated semiconductor chips. Different from the increase in size of the semiconductor chip, packaging techniques have developed to produce smaller and thinner semiconductor packages according to the trends of smaller and lighter electronic products. Ball grid array (BGA) packages have been suggested to meet the demands for thinner and smaller semiconductor packages. A typical BGA package includes a square semiconductor chip mounted on a printed circuit board with terminals which are arrayed in the form of solder balls and protrude from the printed circuit board. The solder balls are designed to be mounted onto a plurality of bonding pads disposed on the surface of the printed circuit board or other suitable substrate.

The solder balls may suffer from shear stress due to difference of coefficient of thermal expansion (CTE) between the semiconductor chip and the substrate during a thermal cycling (TC) test and/or actual use, which may lead to weakness of solder joint reliability. Also, the solder joint reliability may be weakened in drop test for mobile systems such as cellular phones employing BGA packages. The degradation of solder joint reliability may occur due to brittle fracture at interfaces between the bonding pads and the solder balls. These problems may become influential on various semiconductor packages in which semiconductor chips are electrically connected to substrates by solder balls.

### SUMMARY

Example embodiments are directed to semiconductor packages and electronic products employing the same.

In accordance with an example embodiment, a semiconductor package may include an external terminal connected to a concave surface of a bottom pad, wherein the bottom pad is recessed into a substrate.

In accordance with another example embodiment, a semiconductor package may include at least one external terminal, a flexible substrate having a first surface with a plurality of convex portions and a second surface opposite the first surface having a plurality of concave portions, wherein the at least one external terminal is recessed into the substrate and at least one of the concave portions surrounds a portion of the at least one external terminal.

### BRIEF DESCRIPTION OF THE DRAWINGS

Example embodiments will be more clearly understood from the following detailed description taken in conjunction with the accompanying drawings. FIGS. 1-9 represent non-limiting, example embodiments as described herein.

FIGS. 1 to 4 are cross-sectional views illustrating a method for manufacturing a semiconductor package according to an example embodiment of the present invention.

FIG. 5 is an enlarged view illustrating a portion of FIG. 4.

FIG. 6 is a perspective view illustrating a shear stress.

FIG. 7 is a cross-sectional view illustrating a semiconductor package according to another example embodiment of the present invention.

FIG. 8 is a cross-sectional view illustrating a semiconductor package according to still another example embodiment of the present invention.

FIG. 9 is a cross-sectional view illustrating an electronic product employing a semiconductor package according to an example embodiment of the present invention.

### DETAILED DESCRIPTION OF EXAMPLE EMBODIMENTS

Example embodiments will now be described more fully with reference to the accompanying drawings, in which example embodiments are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the sizes of components may be exaggerated for clarity.

It will be understood that when an element or layer is referred to as being “on”, “connected to”, or “coupled to” another element or layer, it can be directly on, connected to, or coupled to the other element or layer or intervening elements or layers that may be present. In contrast, when an element is referred to as being “directly on”, “directly connected to”, or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. Thus, a first element, component, region, layer, or section discussed below could be termed a second element, component, region, layer, or section without departing from the teachings of example embodiments.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments described herein will refer to plan views and/or cross-sectional views by way of ideal schematic views. Accordingly, the views may be modified depending on manufacturing technologies and/or tolerances. Therefore, example embodiments are not limited to those shown in the views, but include modifications in configuration formed on the basis of manufacturing processes. Therefore, regions exemplified in figures have schematic properties and shapes of regions shown in figures exemplify specific shapes or regions of elements, and do not limit example embodiments.

### First Embodiment

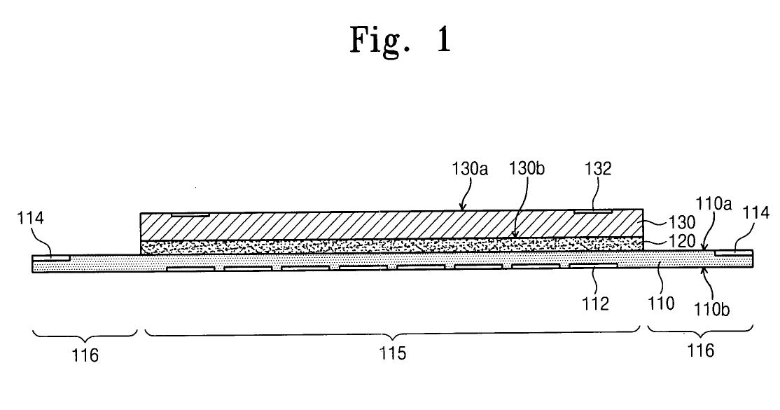

Referring to FIG. 1, a semiconductor chip 130 may be mounted on a substrate 110 with an adhesive layer 120 disposed between the semiconductor chip 130 and the substrate 110. The semiconductor chip 130 may include an active surface 130a on which chip pads 132 and circuit patterns are formed, and an inactive surface 130b opposite the active surface 130a. The chip pads 132 may be formed on an edge of the semiconductor chip 130 and may include a plurality of pads. Alternatively, the chip pads 132 may correspond to redistribution pads which may extend from a center region of the semiconductor chip 130 to the edge of the semiconductor chip 130.

The substrate 110 may be a flexible substrate having a first region 115 and a second region 116 adjacent to the first region 115. In an embodiment, the first region 115 of the substrate 110 may be referred to as a mounting region, and the second region 116 of the substrate 110 may be referred to as a bonding region. The substrate 110 may be formed of material that has a relatively low dielectric constant, relatively moisture-proof characteristics, sufficiently good strength, and sufficient fatigue resistance. For example, the substrate 110 may be a polymer substrate. The mounting region 115 may provide an area on which the semiconductor chip 130 is mounted and the bonding region 116 may be deformed to electrically connect the substrate 110 to the semiconductor chip 130 in a subsequent process.

The substrate 110 may have a top surface 110a to which the inactive surface 130b of the semiconductor chip 130 is attached and a bottom surface 110b opposite the top surface 110a. In addition, top pads 114 may be disposed on a portion of the top surface 110a. Further, bottom pads 112 may be disposed on the bottom surface 110b. The top pads 114 may be disposed in the bonding region 116, and the bottom pads 112 may be disposed in the mounting region 115. The top pads 114 may be electrically connected to the bottom pads 112 through conductive patterns. The bottom pads 112 may be formed of a single layer of material or a multi-level stacked layer which is surface finished with conductive material.

The substrate 110 may have a uniform thickness throughout the substrate 110. Alternatively, the substrate 110 may have a non uniform thickness. For example, a thickness of the mounting region 115 may be greater than that of the bonding region 116. The substrate may also be composed of different materials. For example the mounting region 115 of the substrate 110 may be composed of a material with a higher modulus of elasticity than a material different from a material used to form the bonding regions 116.

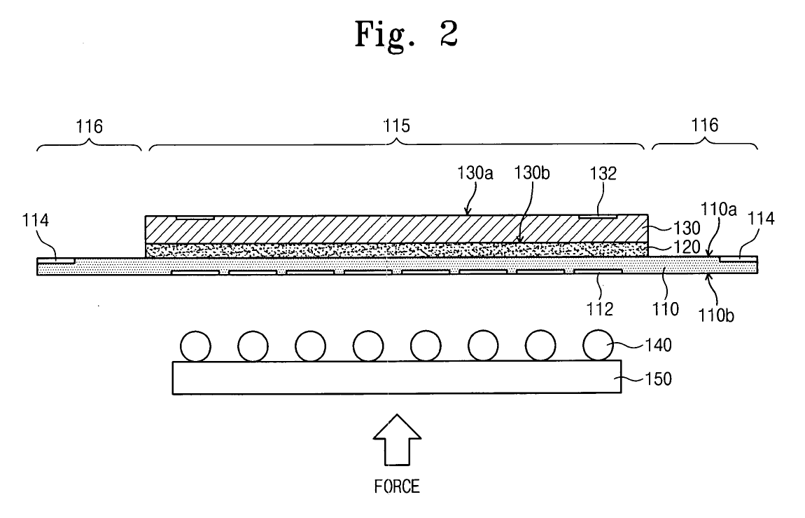

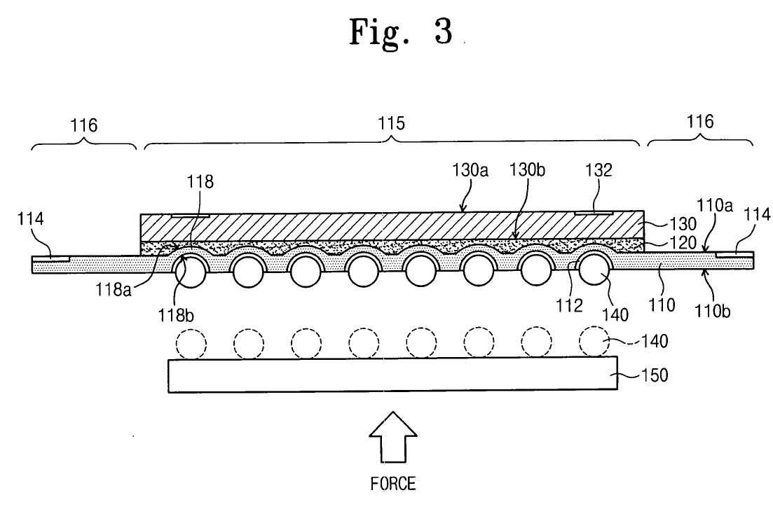

Referring to FIGS. 2 and 3, external terminals, for example, solder balls 140 may be attached to the substrate 110. In one embodiment, the solder balls 140 may be aligned with the bottom pads 112 and then moved toward the bottom pads 112 using an apparatus 150 such as a jig. After the solder balls 140 contact the bottom pads 112, the apparatus 150 may force the solder balls 140 to move toward the semiconductor chip 130 under a relatively high temperature condition to deform the bottom pads 112 into a curved shape as shown in FIG. 3. Alternatively, the solder balls 140 may be formed on the bottom pads 112 using a reflow process, and the solder balls 140 may then be moved toward the semiconductor chip 130 using the apparatus 150 such as the jig at a high temperature. The latter operation may also deform the bottom pads 112 into a curved shape as shown in FIG. 3.

Referring to FIG. 3, the solder balls 140 may be pushed into the substrate 110 when being forced upwardly at a relatively high temperature as described above. Consequently, each bottom pad 112 may be recessed into the substrate 110 to have a concave bottom surface and a convex top surface. In this case, the concave bottom surface of each solder ball 140 may contact and surround a portion of each solder ball 140. Even though the bottom pads 112 are deformed due to the force applied to the solder balls 140, the bottom pads 112 may still have a uniform thickness. The substrate 110 may also be deformed when the apparatus 150 forces the solder balls 140 to move upwardly. That is, some portions of the substrate 110, which are located over the solder balls 140, may protrude toward the semiconductor chip 130, as illustrated in FIG. 3. As a result, a plurality of dimple portions 118 may be formed between the solder balls 140 and the semiconductor chip 130, and the substrate 110 in the mounting region 115 may have an uneven surface profile due to the dimple portions 118. Each of the dimple portions 118 may also include a convex top surface 118a and a concave bottom surface 118b like the bottom pads 112. One of the convex surface 118a and the corresponding concave surface 118b may be positioned above one of the bottom pads 112.

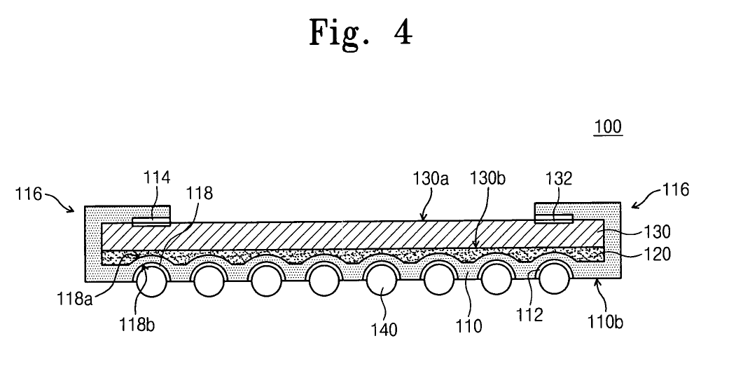

Referring to FIG. 4, the bonding region 116 may be bent toward the active surface 130a of the semiconductor chip 130 so that the top pads 114 are electrically connected to the chip pads 132, thereby yielding a semiconductor package 100 comprising the semiconductor chip 130 electrically connected to the substrate 110 to which the solder balls 140 are attached.

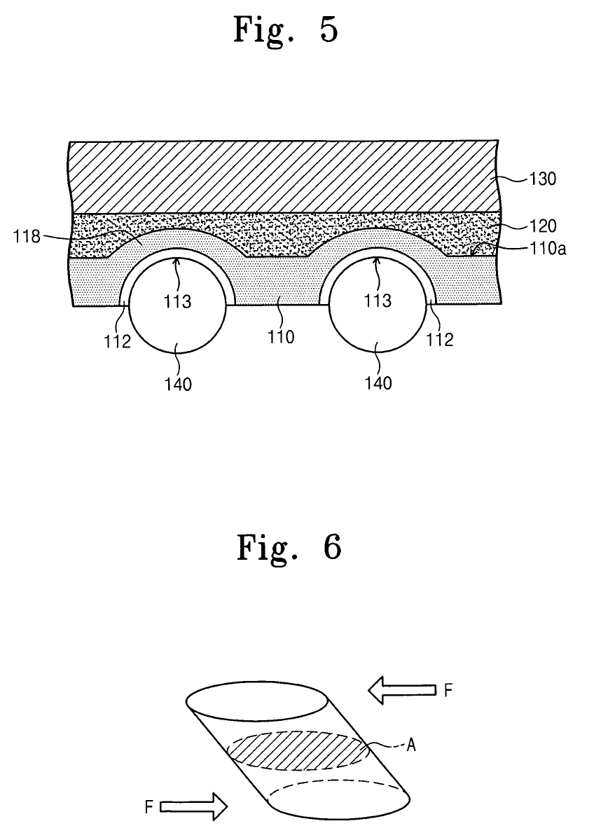

Referring to FIG. 5, as described above, each of the bottom pads 112 may be transformed into the concave shape, which leads to increase of an interface area 113 between the bottom pad 112 and the solder ball 140. The substrate 110 may have a coefficient of thermal expansion (CTE) which is different from a CTE of the semiconductor chip 130. In this case, when the semiconductor package 100 including the semiconductor chip 130 and the substrate 110 is under thermal cycling test and/or actual use, a shear stress may be applied to the solder balls 140 due to the difference between the CTE of the substrate 110 and the CTE of the semiconductor chip 130.

Referring to FIG. 6, shear stress “τ” may be expressed by the following equation.

τ=F/A

where, “F” denotes a force applied over an area “A”.

Referring again to FIG. 5, if the area “A” of the interface 113 between each bottom pad 112 and each solder ball 140 increases, the shear stress τ may be reduced. This is because the shear stress τ is inversely proportional to the interface area “A,” as can be seen from the above equation. In the present embodiment, the bottom pads 112 may be deformed to have the concave bottom surface as described above. Accordingly, the interface area “A” between the bottom pad 112 and the solder balls 140 is increased. Because the interface area between the bottom pads 112 and the solder balls 140 is increased, the shear stress τ between the bottom pads 112 and the solder balls 140 may be significantly reduced as compared with a conventional semiconductor package including flat bottom pads without any deformation thereof. Consequently, the solder joint reliability (SJR) may be improved due to the decrease of the shear stress τ, thereby preventing the solder balls 140 from being destroyed or damaged.

In other embodiments, an adhesive layer 120 may be disposed between the semiconductor chip 130 and the substrate 110. The top surface 110a of the substrate 110 corresponding to an interface between the adhesive layer 120 and the substrate 110 may have an uneven surface because the dimple portions 118 are formed in the mounting region 115 as described above. Even though a peeling phenomenon occurs at the interface between the adhesive layer 120 and the substrate 110 when the semiconductor package 100 is under various reliability tests and/or actual use, the progression of the peeling phenomenon may be alleviated due to the presence of the dimple portions 118.

### Second Embodiment

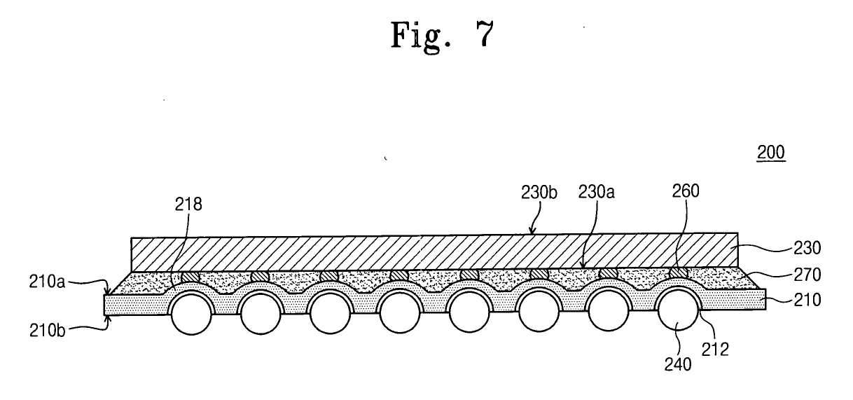

Referring to FIG. 7, a semiconductor package 200 according to a second embodiment may be called an Area Array Flip Chip typed semiconductor package. For example, the semiconductor package 200 may include a flexible substrate 210 with dimple portions 218 and a semiconductor chip 230 mounted on the substrate 210. A bottom surface 210b of the substrate 210 may include concave pads 212 to which solder balls 240 are respectively attached. The semiconductor chip 230 may be mounted on the substrate 210 so that an active surface 230a of the semiconductor chip 230 may face a top surface 210a of the substrate 210. A space between the substrate 210 and the semiconductor chip 230 may be filled with an insulating layer 270 using an under-fill technique.

Electrical interconnection between the substrate 210 and the semiconductor chip 230 may be accomplished using at least one solder bump 260 which may be disposed on the active surface 230a as a conductive connector. The at least one solder bump 260 may include a plurality of solder bumps 260 which may be arrayed regularly over the active surface 230a. The solder bumps 260 may be respectively positioned on the top surface 210a of the substrate 210, for example, on the dimple portions 218. The electrical interconnection length, therefore, may be decreased. At least one of the semiconductor chip 230 and the substrate 210 may include bonding pads (not shown) which may be electrically connected to the solder bumps 260, respectively.

The solder joint reliability (SJR) and/or the interface peeling phenomenon according to the present embodiment may also be improved due to the presence of the dimple portions 218, as described in the first embodiment.

The semiconductor package 200 may be fabricated using the following methods.

In one embodiment, the semiconductor chip 230 may be mounted on the substrate 210 using a flip chip technique. A plurality of solder bumps 260 may be disposed between the top surface 210a of the substrate 210 and the active surface 230a of the semiconductor chip 230. A plurality of bottom pads 212 may be positioned on the bottom surface 210b of the substrate 210. The number and the position of the bottom pads 212 may be identical to those of the solder balls 260.

The solder bumps 260 may be attached to the substrate 210 before mounting the semiconductor chip 230 on the substrate 210. Alternatively, the solder bumps 260 may be attached to the active surface 230a of the semiconductor chip 230 before mounting the semiconductor chip 230 on the substrate 210.

After mounting the semiconductor chip 230, the solder balls 240 may be attached to the bottom pads 212. When the solder balls 240 are attached to the bottom pads 212, the dimple portions 218 may be formed on the substrate 210 due to the same mechanism as described with reference to FIGS. 2 to 3. The solder bumps 260 may be aligned with the dimple portions 218, respectively.

Thereafter, the space between the semiconductor chip 230 and the substrate 210 may be filled with the insulating layer 270 using an under-fill technique.

### Third Embodiment

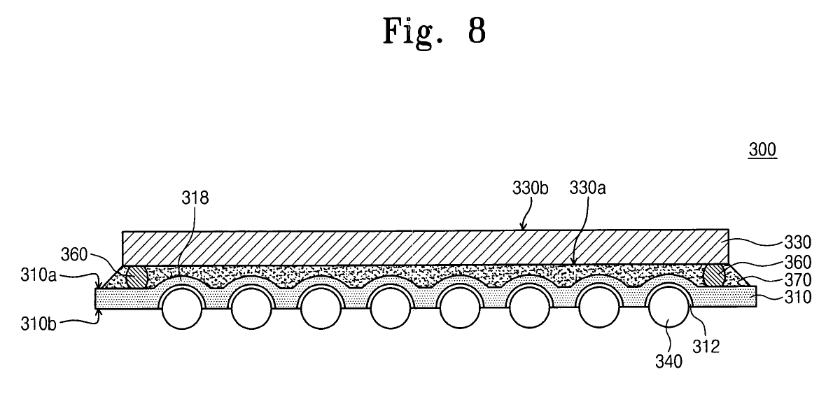

Referring to FIG. 8, a semiconductor package 300 according to a third embodiment of the present invention may be so called a Peripheral Flip Chip typed semiconductor package. In one embodiment, the semiconductor package 300 may include a flexible substrate 310 with dimple portions 318 and a semiconductor chip 330 mounted on the substrate 310. The substrate 310 may include a top surface 310a and a bottom surface 310b opposite the top surface 310a, and the semiconductor chip 330 may include an active surface 330a and an inactive surface 330b opposite the active surface 330a. The semiconductor chip 330 may be mounted on the substrate 310 so that the active surface 330a of the semiconductor chip 330 faces the top surface 310a of the substrate 310. A space between the substrate 310 and the semiconductor chip 330 may be filled with an insulating layer 370 using an under-fill technique.

An electrical interconnection between the substrate 310 and the semiconductor chip 330 may be accomplished using at least one solder bump 360 which may be disposed on an edge of the active surface 330a of the semiconductor chip 330. The at least one solder bump 360, for example, a plurality of solder bumps 360 may be disposed at a region which surrounds the dimple portions 318. That is, the solder bumps 360 may be disposed on a peripheral region of the substrate 310. The dimple portions 318 may function as stand-off-height spacers that maintain a height of the solder bumps 360. The dimple portions 318 may be referred to as the stand-off-height spacers.

The fabrication method and the structural relationships of the other elements which are not mentioned above may be identical or similar to the corresponding descriptions illustrated with reference to FIG. 7. For example, bottom pads 312 illustrated in FIG. 8 may correspond to the bottom pads 212 shown in FIG. 7, and the bottom pads 312 and 212 may be formed using the same method. Similarly, the solder balls 340 illustrate in FIG. 8 may correspond to the solder balls 240 illustrated in FIG. 7, and the solder balls 340 and 240 may be formed using the same method.

### Application Embodiments

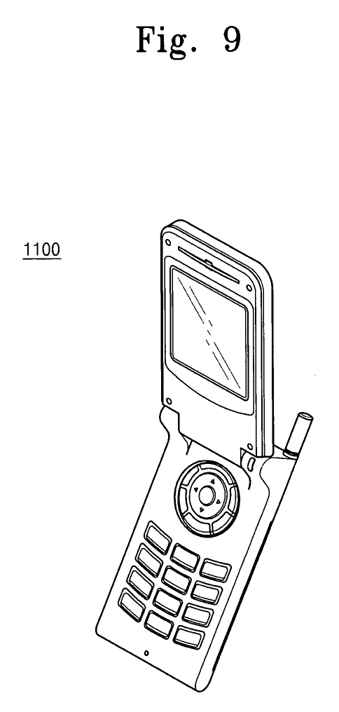

Referring to FIG. 9, at least one of the semiconductor packages 100 to 300 illustrated in FIGS. 4, 7 and 8 may be employed in various electronic products, for example, a mobile phone 1100. Accordingly, the mobile phone 1100 equipped with the at least one of the semiconductor packages 100 to 300 may exhibit an improved electrical reliability and/or an improved mechanical reliability due to improvements of the solder joint reliability and/or the interface peeling phenomenon of the semiconductor packages 100, 200 and 300. Consequently, the mobile phone 1100 may be used and/or tested with reduced mal-functions and/or errors even under relatively severe thermal and mechanical environments. The electronic products are not limited the mobile phone 1100. For example, the electronic products may include laptop computers, desktop computers, cam-coders, game players, portable multimedia players, MP3 players, display devices such as LCD and PDP, memory cards and many others electronic products.

While example embodiments have been particularly shown and described with reference to example embodiments thereof, it will be understood by those of ordinary skill in the art that various changes in form and details may be made therein without departing from the spirit and scope of the following claims.

What is claimed is:

1. A semiconductor package comprising:
an external terminal connected to a concave surface of a bottom pad, wherein the bottom pad is recessed into a substrate.

2. The semiconductor package of claim 1, wherein the substrate includes a top surface and a bottom surface opposite the top surface and the bottom pad is on the bottom surface of the substrate.

3. The semiconductor package of claim 2, wherein the bottom pad surrounds a portion of the external terminal.

4. The semiconductor package of claim 2, wherein the substrate includes at least one dimple portion having a convex top surface and a concave bottom surface opposite the convex top surface, and wherein the concave bottom surface of the dimple portion contacts the bottom pad.

5. The semiconductor package of claim 2, wherein the substrate includes a flexible substrate.

6. The semiconductor package of claim 2, further comprising:
a semiconductor chip on the top surface of the substrate.

7. The semiconductor package of claim 6, wherein the substrate has a first region and a second region adjacent to the first region, and the at least one bottom pad and the semiconductor chip are attached to the first region of the substrate.

8. The semiconductor package of claim 7, wherein
the semiconductor chip has an inactive surface facing the substrate and an active surface with at least one chip pad opposite the inactive surface, and
the substrate includes at least one top pad on the top surface of the second region thereof.

9. The semiconductor package of claim 8, wherein the second region of the substrate is bent toward the active surface of the semiconductor chip so that the top pad is electrically connected to the chip pad.

10. The semiconductor package of claim 6, wherein the semiconductor chip is a flip chip having an active surface facing the substrate and an inactive surface opposite the active surface.

11. The semiconductor package of claim 10, further comprising:
at least one solder bump between the semiconductor chip and the substrate.

12. The semiconductor package of claim 11, wherein the solder bump is disposed to correspond to the external terminal.

13. The semiconductor package of claim 11, wherein the solder bump is disposed on an edge of the semiconductor chip.

14. A semiconductor package comprising:
at least one external terminal; and
a flexible substrate having a first surface with a plurality of convex portions and a second surface opposite the first surface having a plurality of concave portions, wherein the at least one external terminal is recessed into the substrate and at least one of the concave portions surrounds a portion of the at least one external terminal.

15. The semiconductor package of claim 14, further comprising:
a semiconductor chip mounted on the first surface, wherein the at least one external terminal is configured to electrically connect the semiconductor chip to an external device.

16. The semiconductor package of claim 15, wherein the semiconductor chip includes an inactive surface facing the first surface and an active surface opposite the inactive surface.

17. The semiconductor package of claim 16, wherein the flexible substrate includes
a first region including the first surface and the second surface, the first region providing an area on which the semiconductor chip is mounted; and
a second region extending from the first region and joining with the active surface so that the semiconductor chip is electrically connected to the flexible substrate.

18. The semiconductor package of claim 15, wherein the semiconductor chip includes an active surface facing the first surface and an inactive surface opposite the active surface.

19. The semiconductor package of claim 17, further comprising:
a plurality of connectors spread over the active surface, the plurality of connectors configured to electrically connect the semiconductor chip to the flexible substrate.

20. The semiconductor package of claim 14, further comprising:
a concave bottom pad between the external terminal and the substrate, wherein the concave bottom pad contacts a portion of the external terminal.
